(19) United States
(12) Patent Application Publication
(10) Pub. No.: US 2024/0237222 A1
(43) Pub. Date: Jul. 11, 2024

(54) DRIVING CHIP ACCOMMODATING CIRCUIT BOARD AND DISPLAY DEVICE HAVING THE SAME

(71) Applicant: Samsung Display Co., LTD., Yongin-si (KR)

(72) Inventors: HYEONJI KIM, Yongin-si (KR); JUYEOP SEONG, Yongin-si (KR); HEE-KWON LEE, Yongin-si (KR)

(21) Appl. No.: 18/364,578

(22) Filed: Aug. 3, 2023

(30) Foreign Application Priority Data
Jan. 10, 2023 (KR) 10-2023-0003559

(51) Int. Cl. H05K 1/18; H01L 25/18; H05K 1/02; H10K 59/90

(52) U.S. Cl. CPC H05K 1/189; H01L 25/18; H05K 1/0209; H05K 1/0218; H10K 59/90; H05K 2201/0715; H05K 2201/09036; H05K 2201/09063; H05K 2201/10128

(57) ABSTRACT

A display device includes a display substrate including a display area, a pixel in the display area, a pad area adjacent to the display area, and a pad in the pad area, a driving chip on the display substrate, in the pad area, and a circuit board which is on the display substrate and electrically connected to the display substrate at the pad, the circuit board defining a groove of the circuit board and covering the driving chip at the groove.

This application claims priority to Korean Patent Application No. 10-2023-0003559, filed on Jan. 10, 2023, and all the benefits accruing therefrom under 35 U.S.C. § 119, the content of which is herein incorporated by reference in its entirely.

### BACKGROUND

### 1. Field

Embodiments provide generally to display device. More particularly, embodiments relate to a display device that provides visual information.

### 2. Description of the Related Art

With the development of information technology, the importance of a display device, which is a connection medium between a user and information, has been highlighted. For example, the use of display devices such as liquid crystal display device (“LCD”), organic light emitting display device (“OLED”), plasma display device (“PDP”), quantum dot display device or the like is increasing.

### SUMMARY

Embodiments provide a display device with an increased internal utilization space.

A display device according to an embodiment of the present disclosure includes a display substrate including a display area on which a plurality of pixels are disposed and a pad area adjacent to an one side of the display area and having a plurality of pads disposed thereon, a driving chip disposed on the display substrate in the pad area, and a printed circuit board disposed on the display substrate, electrically connected to the plurality of pads, and defining a groove covering the driving chip.

In an embodiment, the printed circuit board as circuit board may include a connection part electrically connected to the plurality of pads, and the connection part may be positioned inside an edge of the printed circuit board.

In an embodiment, the driving chip may be accommodated in the groove. In addition, the driving chip and the printed circuit board may be spaced apart from each other.

In an embodiment, the display device may further include a heat radiating layer disposed in the groove to face the driving chip.

In an embodiment, the heat radiating layer may include at least one of graphite, copper (Cu), and a metal-insulator-metal (MIM) sheet.

In an embodiment, the printed circuit board may include a base layer, a conductive layer disposed on an one surface of the base layer, and a coverlay layer covering the conductive layer.

In an embodiment, the groove may be defined by an opening of the printed circuit board which exposes a part of the conductive layer through the coverlay layer.

In an embodiment, the display substrate may include a first part (or a first area) on which the plurality of pixels are disposed, a second part (or a second area) extending from the first part and having a curvature, and a third part (or a third area) extending from the second part, facing the first part, and having a plurality of pads disposed thereon.

A display device according to an embodiment of the present disclosure includes a display substrate including a display area on which a plurality of pixels are disposed and a pad area adjacent to an one side of the display area and having a plurality of pads disposed thereon, a driving chip disposed on the display substrate in the pad area, a cover panel disposed under the display substrate, and a printed circuit board disposed on the display substrate, electrically connected to the plurality of pads, defining a groove covering the driving chip, and defining a plurality of penetrating holes in an area overlapping the groove on a plane.

In an embodiment, the printed circuit board as a circuit board may include a connection part electrically connected to the plurality of pads, and the connection part may be positioned inside an edge of the printed circuit board.

In an embodiment, the driving chip may be accommodated in the groove. In addition, the driving chip and the printed circuit board may be spaced apart from each other.

In an embodiment, the display device may further include an electromagnetic shielding layer disposed on the printed circuit board in an area overlapping the groove on the plane.

In an embodiment, the electromagnetic shielding layer may extend from the printed circuit board to the cover panel.

In an embodiment, the display device may further include a heat radiating layer disposed on the printed circuit board in an area overlapping the groove on the plane.

In an embodiment, the heat radiating layer may extend from the printed circuit board to the cover panel.

In an embodiment, the heat radiating layer may include at least one of graphite, copper, and a metal-insulator-metal (MIM) sheet.

In an embodiment, the heat radiating layer may include a thermal interface material (TIM).

In an embodiment, the display substrate may include a first part (or a first area) on which the plurality of pixels are disposed, a second part (or a second area) extending from the first part and having a curvature, and a third part (or a third area) extending from the second part, facing the first part, and having the plurality of pads disposed thereon.

A display device according to an embodiment of the present disclosure includes a display substrate including a display area on which a plurality of pixels are disposed and a pad area adjacent to an one side of the display area and having a plurality of pads disposed thereon, a driving chip disposed on the display substrate in the pad area, and a printed circuit board disposed on the display substrate, electrically connected to the plurality of pads, and defining a penetrating hole in an area overlapping the driving chip on a plane.

In an embodiment, the printed circuit board as a circuit board may include a connection part electrically connected to the plurality of pads, and the connection part may be positioned inside an edge of the printed circuit board.

A display device according to an embodiment of the present disclosure may include a printed circuit board disposed on a display substrate and defining a groove at which a driving chip disposed on the display substrate in a pad area is covered.

As the printed circuit board defines the groove in which the driving chip is accommodated, an area as an overlapping (planar) area where the printed circuit board overlaps the pad area of the display substrate may relatively increase. As a result, a space of the display device in which an external device may be disposed under the display substrate of the display device may relatively increase.

In addition, a display device according to an embodiment of the present disclosure may include a printed circuit board disposed on a display substrate, defining a groove covering a driving chip, and defining a plurality of penetrating holes in an area overlapping the groove on a plane.

Accordingly, heat generated from the driving chip may be dissipated to the outside of the display device through the plurality of penetrating holes as a heat dissipating member. That is, the heat generated from the driving chip may be effectively dissipated.

### BRIEF DESCRIPTION OF THE DRAWINGS

Illustrative, non-limiting embodiments will be more clearly understood from the following detailed description in conjunction with the accompanying drawings.

FIG. 1A is a plan view illustrating a display device according to an embodiment of the present disclosure.

FIG. 1B is a diagram illustrating a bent shape of the display device of FIG. 1A.

FIG. 2 is a cross-sectional view taken along line I-I′ of FIG. 1A.

FIG. 3 is a cross-sectional view taken along line II-II′ of FIG. 1A.

FIG. 4A is a plan view illustrating the display device of FIG. 1A.

FIG. 4B is a cross-sectional view illustrating the display device of FIG. 1A.

FIG. 5 is an enlarged cross-sectional view of area ‘A’ of FIG. 4B.

FIG. 6 is a plan view illustrating a printed circuit board included in the display device of FIG. 1A.

FIG. 7 is a cross-sectional view illustrating a display device according to an embodiment of the present disclosure.

FIG. 8 is a cross-sectional view illustrating a display device according to an embodiment of the present disclosure.

FIG. 9 is a cross-sectional view illustrating a printed circuit board included in the display device of FIG. 8.

FIG. 10 is a cross-sectional view illustrating a display device according to an embodiment of the present disclosure.

FIGS. 11A and 11B are plan views illustrating a printed circuit board included in the display device of FIG. 10.

FIGS. 12A and 12B are cross-sectional views illustrating a display device according to an embodiment of the present disclosure.

FIGS. 13A and 13B are cross-sectional views illustrating a display device according to an embodiment of the present disclosure.

FIG. 14A is a plan view illustrating a display device according to an embodiment of the present disclosure.

FIG. 14B is a cross-sectional view illustrating the display device of FIG. 14A.

FIG. 14C is a plan view illustrating a printed circuit board included in the display device of FIG. 14A.

### DETAILED DESCRIPTION

Hereinafter, embodiments of the present disclosure will be described in detail with reference to the accompanying drawings. The same reference numerals are used for the same components in the drawings, and redundant descriptions of the same components will be omitted.

In this specification, it will be understood that when an element is referred to as being “on”, “connected to”, or “coupled to” another element, it may be directly on, connected, or coupled to the other element or one or more intervening elements may also be present. In contrast, when an element is referred to as being “directly on”, “directly connected to”, or “directly coupled to” another element, no other element or intervening element is present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” Within the Figures and the text of the disclosure, a reference number indicating a singular form of an element may also be used to reference a plurality of the singular element.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

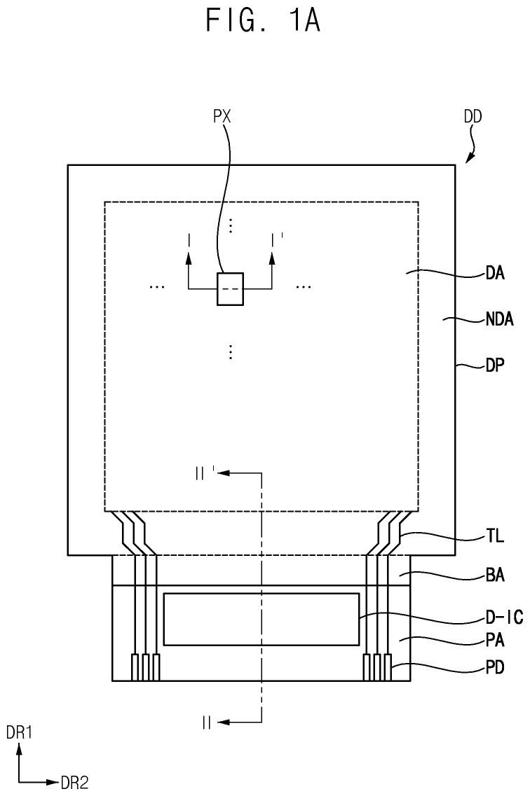

FIG. 1A is a plan view illustrating a display device DD according to an embodiment of the present disclosure. FIG. 1B is a diagram illustrating a bent shape of the display device DD of FIG. 1A, that is, the display device DD which is bent.

In this specification, a plane may be defined by a first direction DR1 and a second direction DR2 which crosses the first direction DR1. For example, the first direction DR1 and the second direction DR2 may be perpendicular to each other. The display device DD and various components or layers thereof may have a thickness extended along a third direction which crosses or intersects the plane, that is, each of the first direction DR1 and the second direction DR2.

Referring to FIGS. 1A and 1B, a display device DD according to an embodiment of the present disclosure may include a display panel DP and a driving chip D-IC.

The display panel DP may include a display area DA, a non-display area NDA, a bending area BA, and a pad area PA including a pad PD provided in plural including a plurality of pads PD. A display pixel (e.g., a pixel PX) provided in plural including a plurality of pixels PX for generating an image, may be disposed in the display area DA. The image may be generated by combining light emitted from each of the pixels PX. For example, the pixels PX may be arranged in a matrix form within the display area DA, along the first direction DR1 and the second direction DR2. Various components and layers of the display device DD may include a display area DA, a non-display area NDA, a bending area BA, and a pad area PA corresponding to those planar areas described above.

The non-display area NDA may be positioned adjacent to the display area DA, such as being around the display area DA in the plan view (e.g., a view of the plane defined by the first direction DR1 and the second direction DR2 crossing each other). For example, the non-display area NDA may extend along an outer edge of or surround at least a part of the display area DA. The non-display area NDA may be an area (e.g., a planar area) not displaying the image.

As illustrated in FIG. 1B, the bending area BA at which the display device DD (or the display panel DP is bendable) may extend from one side of the non-display area NDA. In the display device DD which is bent (refer to FIG. 1B), various components or layer may be bent downward. That is, when the display device DD is bent at the bending area BA about a bending axis extending along the second direction DR2, the pad area PA may extend from the bending area BA and be positioned under the display area DA and/or the non-display area NDA along the thickness direction of the display device DD.

As illustrated in FIG. 1A, in the display device DD which is unfolded, the bending area BA may be positioned between the display area DA and the pad area PA. That is, the display area DA, a portion of the non-display area NDA, the bending area BA and the pad area PA may be in order. The bending area BA and/or the pad area PA may be considered a portion of the non-display area NDA, without being limited thereto.

The display panel DP may include a plurality of transfer lines TL connecting the display area DA and the pad area PA to each other. The transfer line TL may transmit an electrical signal between the two areas. Each of the transfer lines TL may include a first end positioned in the pad area PA and a second end which is opposite to the first and adjacent to the display area DA. That is, the second end of the transfer line TL may be closer to the display area DA than the first end.

The first end of each of the transfer lines TL may be connected to a corresponding one of the plurality of pads PD. The second end of each of the transfer lines TL may be connected to a corresponding line among a plurality of lines (e.g., signal lines such as gate lines, data lines, driving voltage lines, etc.) disposed in the display area DA. The pads PD (e.g., the non-display area NDA) and the pixels PX (e.g., the display area DA) may be electrically connected to each other through the transfer lines TL.

The driving chip D-IC may be disposed on the display panel DP, in the pad area PA. The driving chip D-IC may include a bump provided in plural including a plurality of bumps at which the driving chip D-IC is connected to the pads PD. The driving chip D-IC may provide driving signals as electrical signals, to the display panel DP. The driving signals may refer to various electrical signals for driving the display panel DP, such as a driving voltage, a control signal, a data signal, etc. The driving signals may be transferred to the pixels PX disposed in the display area DA, through the pads PD and the transfer lines TL.

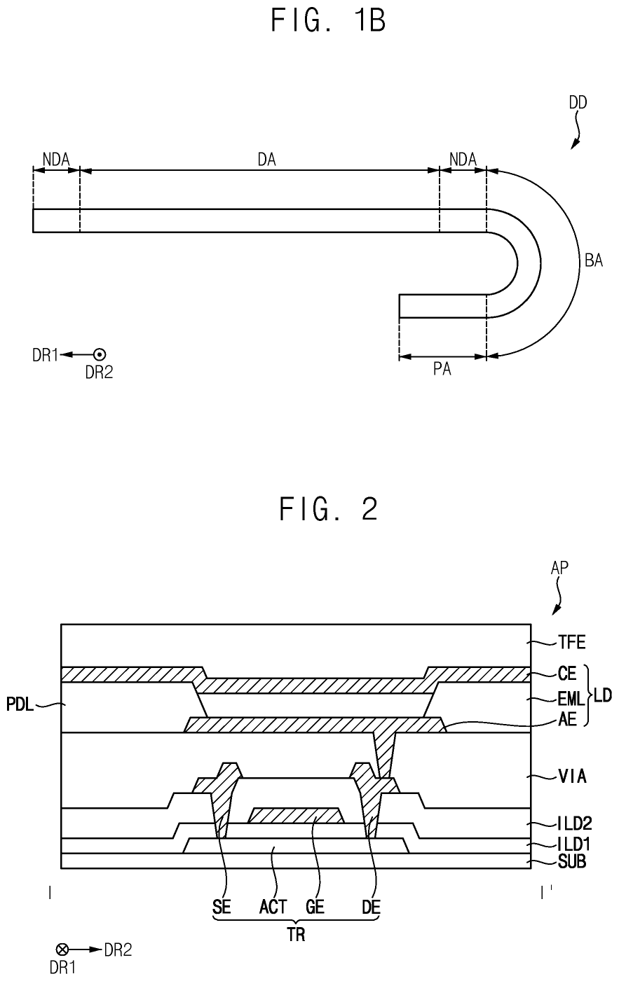

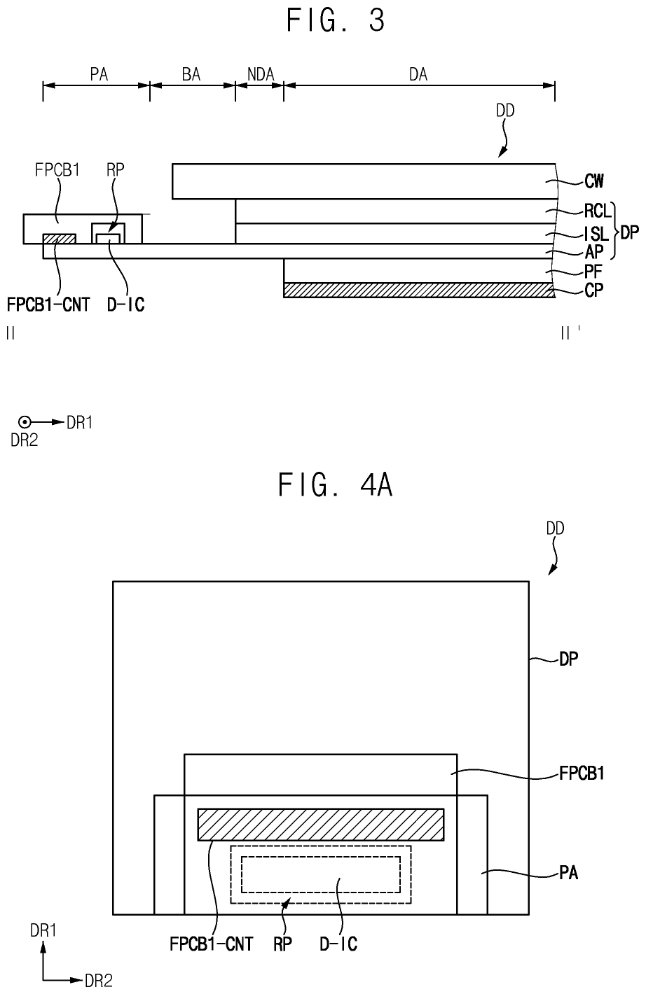

FIG. 2 is a cross-sectional view taken along line I-I′ of FIG. 1A. FIG. 3 is a cross-sectional view taken along line II-II′ of FIG. 1A. For example, FIG. 3 is a cross-sectional view illustrating the display device DD which is flat or unfolded, or before or after being bent.

Referring to FIGS. 2 and 3, the display device DD according to an embodiment of the present disclosure may include a cover window CW, the display panel DP, a protective layer PF, a cover panel CP, the driving chip D-IC, and a first printed circuit board FPCB1. Here, the display panel DP may include an anti-reflection layer RCL, a touch layer ISL, and a display substrate AP.

As illustrated in FIG. 2, a portion of the display substrate AP at the display area DA may include a base substrate SUB, a thin film transistor TR as a transistor, a first insulating layer ILD1, a second insulating layer ILD2, a via insulating layer VIA, a light emitting element LD of a light emitting element layer (or image display layer), a pixel defining layer PDL, and an encapsulation layer TFE. Here, the thin film transistor TR may include an active layer ACT, a gate electrode GE, a source electrode SE, and a drain electrode DE. The light emitting element LD may include a lower electrode AE, a light emitting layer EML, and an upper electrode CE. The structures and patterns in FIG. 2 may be repeated or provided in plural within the display area DA.

The base substrate SUB may include a transparent material or an opaque material. The base substrate SUB may be formed of (or include) a transparent resin substrate. A polyimide substrate may be an example of the transparent resin substrate. In this case, the polyimide substrate may include a first organic layer, a first barrier layer, a second organic layer, etc. Alternatively, the base substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

A buffer layer (not shown) may be disposed on the base substrate SUB. The buffer layer may prevent diffusion of metal atoms or impurities from the base substrate SUB to an upper structure (e.g., the thin film transistor TR, the light emitting element LD, etc.) of the display substrate AP. In addition, the buffer layer may obtain the substantially uniform active layer ACT with respect to crystallization, conductivity, doping, etc. by controlling a heat transfer rate during a crystallization process of an active layer material for forming or providing the active layer ACT. In addition, the buffer layer may serve to improve flatness of the surface of the base substrate SUB when the surface of the base substrate SUB is not uniform. For example, the buffer layer may include an organic insulating material and/or an inorganic insulating material. Alternatively, the buffer layer may be omitted.

The active layer ACT as an active layer pattern may be disposed on the base substrate SUB. The active layer ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The silicon semiconductor may include amorphous silicon, polycrystalline silicon, etc. The active layer ACT may include or define a source area, a drain area, and a channel area positioned between the source area and the drain area.

The first insulating layer ILD1 may be disposed on the active layer ACT and the base substrate SUB. The first insulating layer ILD1 may cover the active layer ACT on the base substrate SUB, and may be disposed along the profile of the active layer ACT (e.g., a cross-sectional profile or shape), to have a uniform thickness in directions normal to various positions along the underlying stack of layers. Alternatively, different from that shown in FIG. 2, the first insulating layer ILD1 may sufficiently cover the active layer ACT and may have a substantially flat upper without creating a step difference around the active layer ACT.

A contact hole may be defined in or by the first insulating layer ILD1. The contact hole may expose a part of the active layer ACT to outside the first insulating layer ILD1. A solid portion of the first insulating layer ILD1 may include a sidewall which defines the contact hole. The first insulating layer ILD1 may include a silicon compound, a metal oxide, etc. Examples of the silicon compound may include silicon oxide (SiOₓ), silicon nitride (SiNₓ), silicon oxynitride (SiOₓN_{y}), etc. These may be used alone or in combination with each other.

The gate electrode GE as a gate pattern of a conductive pattern layer may be disposed on the first insulating layer ILD1. The gate electrode GE may partially overlap the active layer ACT on a plane. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The second insulating layer ILD2 may be disposed on the gate electrode GE and the first insulating layer ILD1. The second insulating layer ILD2 may cover the gate electrode GE on the first insulating layer ILD1, and may be disposed along the profile of the gate electrode GE to have a uniform thickness. Alternatively, different from that shown in FIG. 2A, the second insulating layer ILD2 may sufficiently cover the gate electrode GE on the first insulating layer ILD1 and may have a substantially flat upper surface without creating a step difference around the gate electrode GE.

A contact hole may be defined in or by the second insulating layer ILD2, similar to that described herein for other layers. The contact hole may expose a part of the active layer ACT similar to that described herein for other layers. The second insulating layer ILD2 may include an inorganic insulating material. For example, the second insulating layer ILD2 may include a silicon compound, a metal oxide, etc.

The source electrode SE and the drain electrode DE of a conductive pattern layer may be disposed on the second insulating layer ILD2. Each of the source electrode SE and the drain electrode DE may be electrically connected to the active layer ACT through a respective contact hole formed in the first insulating layer ILD1 and the second insulating layer ILD2. Each of the source electrode SE and the drain electrode DE may include a metal, an alloy, a metal nitride, a conductive metal oxide, a transparent conductive material, etc. These may be used alone or in combination with each other. Accordingly, the thin film transistor TR including the active layer ACT, the gate electrode GE, the source electrode SE, and the drain electrode DE may be formed or provided.

The via insulating layer VIA may be disposed on the second insulating layer ILD2. For example, the via insulating layer VIA may be disposed on the second insulating layer ILD2 with a relatively large thickness to sufficiently cover the source electrode SE and the drain electrode DE. A contact hole may be defined in the via insulating layer VIA similar to that described herein for other layers. The contact hole may expose a part of the drain electrode DE similar to that described herein for other layers. The via insulating layer VIA may include an organic insulating material or an inorganic insulating material. In an embodiment, the via insulating layer VIA may include an organic insulating material. For example, the via insulating layer VIA may include photoresist, polyacryl-based resin, polyimide-based resin, polyamide-based resin, siloxane-based resin, acryl-based resin, epoxy-based resin, etc. These may be used alone or in combination with each other.

The lower electrode AE may be disposed on the via insulating layer VIA. The lower electrode AE may be electrically connected to the drain electrode DE at or through a contact hole formed in the via insulating layer VIA. As a result, the lower electrode AE may be electrically connected to the thin film transistor TR. The lower electrode AE may include a metal, an alloy, a metal nitride, a conductive metal oxide, a transparent conductive material, etc. These may be used alone or in combination with each other. For example, the lower electrode AE may be referred to as an anode electrode.

The pixel defining layer PDL may be disposed on the via insulating layer VIA. The pixel defining layer PDL may cover an edge of the lower electrode AE and may expose a part of an upper surface of the lower electrode AE similar to that described herein for other layers. The pixel defining layer PDL may define an opening similar to that described herein for the contact holes in other respective layers, where the opening exposes the lower electrode AE to outside the pixel defining layer PDL.

The pixel defining layer PDL may include an organic insulating material or inorganic insulating material. The organic insulating material may include photoresist, polyacryl-based resin, polyimide-based resin, acryl-based resin, etc. These may be used alone or in combination with each other. In an embodiment, the pixel defining layer PDL may further include an inorganic material or organic material including a light blocking material with black color.

The light emitting layer EML may be disposed on the lower electrode AE, at least partially of which is exposed to outside the pixel defining layer PDL. The light emitting layer EML may include one or both of an organic light emitting material and a quantum dot. For example, the organic light emitting material may include a low-molecular-weight organic compound or a high-molecular-weight organic compound. Examples of the low-molecular-weight organic compound may include copper phthalocyanine, N,N′-diphenylbenzidine, tri-(8-hydroxyquinoline)aluminum, etc. Examples of the high-molecular-weight organic compound may include poly(3,4-ethylenedioxythiophene, polyaniline, poly-phenylenevinylene, polyfluorene, etc. These may be used alone or in combination with each other.

The upper electrode CE may be disposed on the pixel defining layer PDL and the light emitting layer EML. For example, the upper electrode CE may include a metal, an alloy, a metal nitride, a conductive metal oxide, a transparent conductive material, etc. These may be used alone or in combination with each other. For example, the upper electrode CE may be referred to as a cathode electrode. Accordingly, the light emitting element LD including the lower electrode AE, the light emitting layer EML, and the upper electrode CE may be formed or provided.

The encapsulation layer TFE may be disposed on the upper electrode CE. The encapsulation layer TFE may prevent impurities, moisture, and the like from permeating the light emitting element LD from outside of the display substrate AP (or outside of the display panel DP, the display device DD, etc.). The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc., and the organic encapsulation layer may include a polymer cured material such as polyacrylate. In an embodiment, the encapsulation layer TFE may include a first inorganic encapsulation layer disposed on the upper electrode CE, an organic encapsulation layer disposed on the first inorganic encapsulation layer, and a second inorganic encapsulation layer disposed on the organic encapsulation layer.

In addition, although the display device DD of the present disclosure is described by limiting the display device DD with structures of an organic light emitting display device (“OLED”), the configuration of the present disclosure is not limited thereto. In other embodiments, the display device DD may include a liquid crystal display device (“LCD”), a field emission display device (“FED”), a plasma display device (“PDP”), an electrophoretic image display device (“EPD”), an inorganic light emitting display device (“ILED”), or a quantum dot display device.

As illustrated in FIG. 3, the touch layer ISL may be disposed on the display substrate AP to face the display substrate AP. The touch layer ISL may sense an external input such as a touch input. The touch layer ISL may include a plurality of touch electrodes. The touch layer ISL may be provided as a panel or film separate from the display panel DP and attached to the display panel DP, or may be provided as a common layer inside the display panel DP.

The anti-reflection layer RCL may be disposed on the touch layer ISL. External light may be incident to the display device DD from outside thereof, and the external light may be reflected from various electrodes or lines (e.g., conductive lines, signal lines, etc.) included in the display substrate AP. The anti-reflection layer RCL may prevent the external light from being recognized as the external light is reflected.

The anti-reflection layer RCL may include a polarizer and/or a phase retarder. The number of the phase retarder and the phase delay length (λ/4 or λ/2) of the phase retarder may be determined according to the operating principle of the anti-reflection layer RCL. Alternatively, the anti-reflection layer RCL may include color filters. The color filters may have a predetermined arrangement. The color filters may be arranged in consideration of emission colors of pixels PX (of FIG. 1) included in the display substrate AP. In addition, the anti-reflection layer RCL may further include a black matrix adjacent to the color filters. When the touch layer ISL is omitted, the anti-reflection layer RCL may be attached on the display substrate AP. Omission of the touch layer ISL may provide the anti-reflection layer RCL in contact with the display substrate AP, such as in direct contact, without being limited thereto. As being in contact, elements may form an interface therebetween, without being limited thereto.

The cover window CW may be disposed on the anti-reflection layer RCL. The cover window CW may serve to cover and protect the display panel DP. The cover window CW may provide an outer surface of the display device DD. The cover window CW may be on a display surface of the display panel DP, as a front surface of the display panel DP. The cover window CW may be attached to one surface of the display panel DP through an adhesive including a pressure sensitive adhesive film (“PSA film”), an optically clear adhesive film (“OCA film”), an optically clear resin (“OCR”), etc. When the display device DD includes the anti-reflection layer RCL, the cover window CW may be attached to an upper surface of the anti-reflection layer RCL.

The cover window CW may include a window substrate and a pattern such as a printed layer. The window substrate may include a transparent material. For example, the window substrate may include glass or plastic. The printed layer may be disposed on the window substrate. The printed layer may be disposed on an edge part of the window substrate including the outer edge and a portion of the window substrate which is extended from the outer edge, and may be disposed in the non-display area NDA (of FIG. 1). The printed layer may be a light blocking layer.

The protective layer PF may be disposed under the display panel DP. The protective layer PF may face the cover member CW with the display panel DP therebetween. The protective layer PF may protect components of the display panel DP from external impact. In addition, the protective layer PF may prevent scratches from being generated on a rear surface of components of the display panel DP during a process of manufacturing or providing the display panel DP, where the rear surface is opposite to the front surface of the display panel DP along the thickness direction. The protective layer PF may include a flexible film. For example, the protective layer PF may include polyethylene terephthalate film (“PET film”).

The cover panel CP may be disposed under the display panel DP. Specifically, the cover panel CP may be disposed under the protective layer PF. The cover panel CP may protect components of the display panel DP from external impact.

The driving chip D-IC may be disposed on the display substrate AP in the pad area PA (of FIG. 1). The driving chip D-IC may provide driving signals to the display panel DP. The driving signals may refer to various signals as electrical signals for driving the display panel DP, such as a driving voltage, a control signal, a data signal, etc.

A height or thickness of components or layers may be defined along the thickness direction (e.g., the third direction). The height or thickness may be defined relative a reference element or reference surface. The height or thickness may be a maximum distance relative to the reference, without being limited thereto. The height or thickness of an element may be a total or overall thickness, including all the thickness portions of various component or layers within such element. For example, a height of the driving chip D-IC from the display substrate AP (as the reference) may be about 180 micrometers.

The first printed circuit board FPCB1 may be disposed on the display substrate AP. Specifically, the first printed circuit board FPCB1 may be disposed on the display substrate AP to overlap a part of the pad area PA. Accordingly, the first printed circuit board FPCB1 may be electrically connected to the display panel DP (or the display substrate AP) at a plurality of pads PD (of FIG. 1) disposed in the pad area PA. That is, the first printed circuit board FPCB1 may include a connection part FPCB1-CNT at which the first printed circuit board FPCB1 is electrically connected to the plurality of pads PD. This will be described layer with reference to FIG. 6.

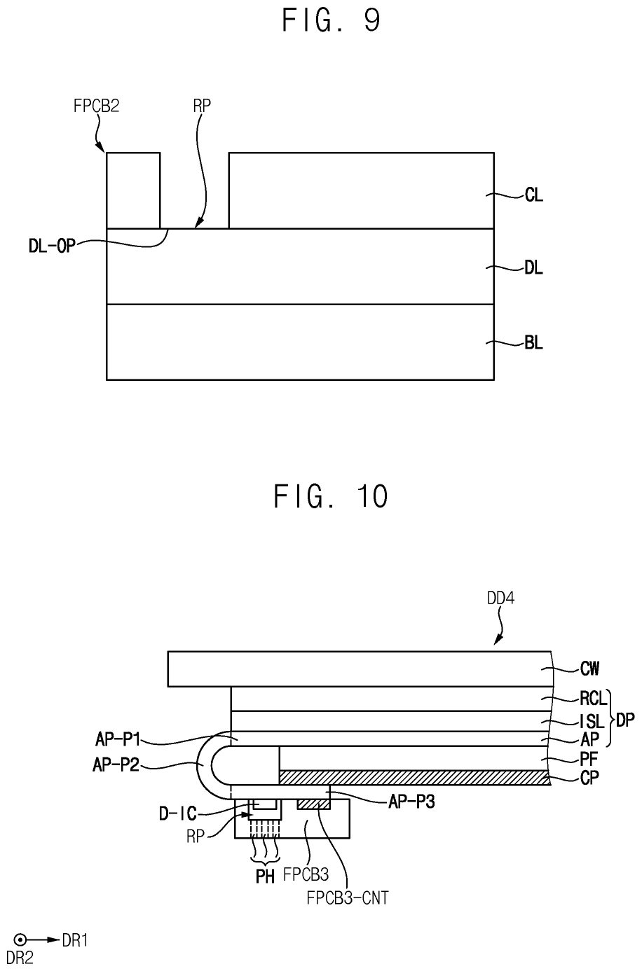

The first printed circuit board FPCB1 may include a base layer BL (of FIG. 9), a conductive layer DL (of FIG. 9) disposed on one surface of the base layer BL, and a coverlay layer CL (of FIG. 9) covering the conductive layer DL. The base layer BL may include a synthetic resin. For example, the base layer may include a polyimide-based resin. The conductive layer DL may include a plurality of lines (e.g., conductive lines, signal lines, etc.). The conductive layer DL may be connected to the pads PD disposed on the display substrate AP in the pad area PA, through an anisotropic conductive film (“ACF”).

The conductive layer DL may include a metal, an alloy, a metal nitride, a conductive metal oxide, a transparent conductive material, etc. Examples of material that may be used as the conductive layer DL may include aluminum (Al), an alloy containing aluminum, aluminum nitride (AlN), copper (Cu), nickel (Ni), platinum (Pt), etc. These may be used alone or in combination with each other. The coverlay layer CL may serve to protect and insulate the conductive layer DL. For example, a height of the first printed circuit board FPCB1 from the display substrate AP may be about 300 micrometers to about 310 micrometers.

Referring to FIG. 3, for example, the first printed circuit board FPCB1 may define a groove RP which is open to outside the first printed circuit board FPCB1. A solid portion of the first printed circuit board FPCB1 may define the groove RP, similar to defining of an opening, contact hole, etc. The groove RP may have a depth taken from a surface of the first printed circuit board FPCB1 at which the groove RP is open. The first printed circuit board FPCB1 may extend further than an end portion of the display substrate AP, so as to define an extended portion of the first printed circuit board FPCB1.

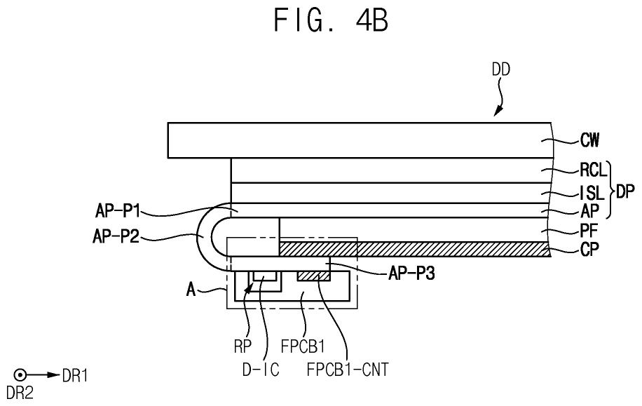

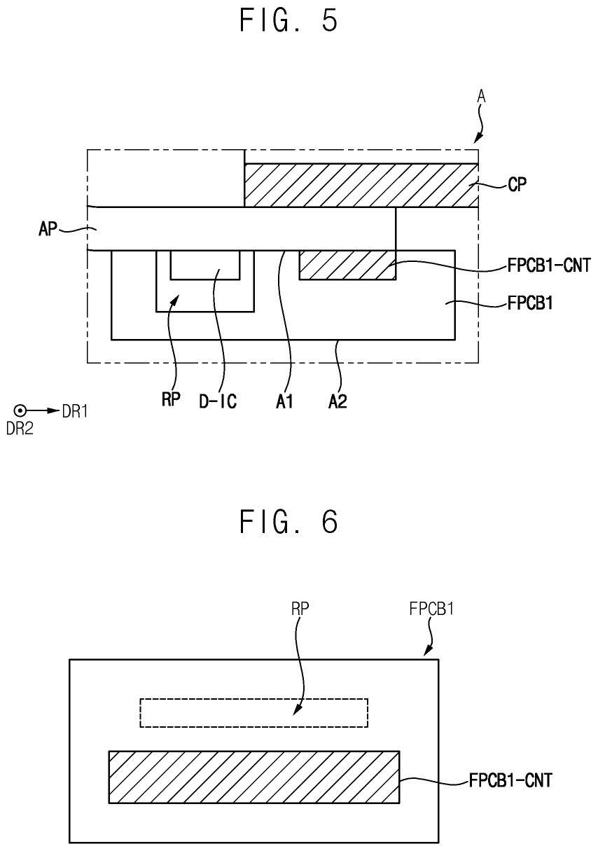

The first printed circuit board FPCB1 may cover the driving chip D-IC on the display substrate AP. That is, the groove RP may be open at a first surface A1 (of FIG. 5) of the first printed circuit board FPCB1 which is closest to and/or in contact with the display substrate AP. The groove RP is recessed toward a second surface A2 (of FIG. 5) of the first printed circuit board FPCB1 which is opposite to the first surface A1. This will be described later with reference to FIGS. 4A, 4B, 5, and 6.

FIG. 4A is a plan view illustrating the display device DD of FIG. 1A. For example, FIG. 4A is a plan view illustrating a bent state of the display device DD. FIG. 4A may be a rear view of the display device DD which is bent, such that the driving chip D-IC is shown in dotted line along with the groove RP. FIG. 4B is a cross-sectional view illustrating the display device of FIG. 1A. For example, FIG. 4B is a cross-sectional view illustrating a bent state of the display device DD, such as the structure in FIG. 4A. FIG. 5 is an enlarged cross-sectional view of area ‘A’ of FIG. 4B. FIG. 6 is a plan view illustrating a printed circuit board as a circuit board included in the display device DD of FIG. 1A. Hereinafter, descriptions overlapping descriptions of the display device DD described with reference to FIGS. 2 and 3 will be omitted or simplified.

Referring to FIGS. 4A, 4B, 5, and 6, the display device DD according to an embodiment of the present disclosure may include the cover window CW, the display panel DP, the protective layer PF, the cover panel CP, the driving chip D-IC, and the first printed circuit board FPCB1. Here, the display panel DP may include the anti-reflection layer RCL, the touch layer ISL, and the display substrate AP. Various components or layers of the display device DD which is bendable (or foldable or rollable), may be bendable together with each other.

The display substrate AP may include a base substrate SUB (of FIG. 2) that is flexible and an encapsulation layer TFE (of FIG. 2) that is flexible. Accordingly, a part of the display substrate AP may be bendable, foldable or rollable such as to be bent, folded or rolled. Specifically, the display substrate AP which is bent may include a first part AP-P1 (e.g., a first area) on which the plurality of pixels PX are disposed, a second part AP-P2 (e.g., a second area) extending from the first part AP-P1 and being bendable to define a predetermined curvature in a bent state, and a third part AP-P3 (e.g., a third area) extending from the second part AP-P2, facing the first part AP-P1 within the display substrate AP which is bent, and having the plurality of pads PD disposed thereon. As a part of the display substrate AP is bent, the third part AP-P3 of the display substrate AP may be disposed under the cover panel CP along the thickness direction. The first part AP-P1, the second part AP-P2 and the third part AP-P3 may be in order along the first direction DR1, where the third part AP-P3 defines the end portion of the display substrate AP.

The first printed circuit board FPCB1 may be disposed on the display substrate AP. Specifically, the first printed circuit board FPCB1 may be disposed on the display substrate AP to overlap the third part AP-P3 of the display substrate AP. That is, as a part of the display substrate AP is bent, the first printed circuit board FPCB1 may be disposed under the cover panel CP together with the third part AP-P3.

The first printed circuit board FPCB1 may be electrically connected to the plurality of pads PD disposed on the third part AP-P3 of the display substrate AP. That is, the first printed circuit board FPCB1 may include the connection part FPCB1-CNT at which the first printed circuit board FPCB1 is electrically connected to the plurality of pads PD. Referring to FIG. 3, for example, the connection part FPCB1-CNT may be coplanar with the driving chip D-IC and/or the groove RP.

As illustrated in FIG. 6, in an embodiment, the connection part FPCB1-CNT of the first printed circuit board FPCB1 may be positioned inside an edge of the first printed circuit board FPCB1, that is, within a planar area of the circuit board, being spaced apart from outer edges of the first printed circuit board FPCB1 in the plan view, etc. Accordingly, compared to the case where a conventional connection part of the first printed circuit board FPCB1 is positioned at or corresponding to the edge of the first printed circuit board FPCB1, an area (e.g., a planar area) where the first printed circuit board FPCB1 overlaps the pad area PA of the display substrate AP may relatively increase. Here, a decreased overlapping area where a conventional circuit board overlaps the pad area PA of the display substrate AP reduces a space adjacent to the circuit board within a bent display device since the conventional circuit boards extends further under the display substrate AP in a direction away from the bending area BA. That is, the space for an external device may be defined within a bent display device, where the space is adjacent to the circuit board and below the display substrate AP.

In one or more embodiment, the driving chip I-C and the connection part FPCB1-CNT of the first printed circuit board FPCB1 may be positioned within a planar area of the first printed circuit board FPCB1. As a result, a utilization space under the display substrate AP may relatively increase. Specifically, the utilization space under the cover panel CP that does not overlap the third part AP-P3 of the display substrate AP in a plan view may be relatively increase. In other words, a space in which an external device may be disposed under the cover panel CP may relatively increase.

As illustrated in FIG. 5, the first printed circuit board FPCB1 may define the groove RP covering the driving chip D-IC. That is, the groove RP may refer to a part of the first printed circuit board FPCB1 which is defined by portions of a first surface A1 which are in contact with the display substrate AP, and the groove RP is recessed toward a second surface A2 of the first printed circuit board FPCB1. The groove RP may have a rectangular shape in a plan view (e.g., a planar shape), but the present disclosure is not limited thereto. For example, the groove RP may have a rectangular planar shape with rounded corners.

As illustrated in FIG. 6, the groove RP may be defined inside the edge of the first printed circuit board FPCB1, such as to be spaced apart from outer edges of the first printed circuit board FPCB1. However, the present disclosure is not limited thereto, and the groove RP may be defined at a part of the first printed circuit board FPCB1 which is adjacent to the edge of the first printed circuit board FPCB1.

The driving chip D-IC may be disposed on the display substrate AP in the pad area PA. In an embodiment, the driving chip D-IC may be accommodated in the groove RP and may be spaced apart from the first printed circuit board FPCB1. A space or gap may be defined between a distal end of the driving chip D-IC and inner surfaces of the first printed circuit board FPCB1 which define the groove RP. A space or gap may be defined between one or more outer surface among the outer side surfaces of the driving chip D-IC, and the inner surfaces. In an embodiment, an inner wall of the circuit board defines the groove RP of the circuit board, and the driving chip D-IC is in the groove RP of the circuit board and is spaced apart from the inner wall of the circuit board.

In an embodiment, the driving chip D-IC may be accommodated in the groove RP and may contact the first printed circuit board FPCB1 at one or more of the inner surfaces thereof.

As the first printed circuit board FPCB1 defines the groove RP in which the driving chip D-IC is accommodated, a planar area where the first printed circuit board FPCB1 overlaps the pad area PA of the display substrate AP (e.g., an overlapping area) may relatively increase. As a result, a utilization space under the display substrate AP may relatively increase. Specifically, the utilization space under the cover panel CP that does not overlap the third part AP-P3 of the display substrate AP in a plan view may be relatively increase. In other words, a space in which an external device may be disposed under the cover panel CP may relatively increase.

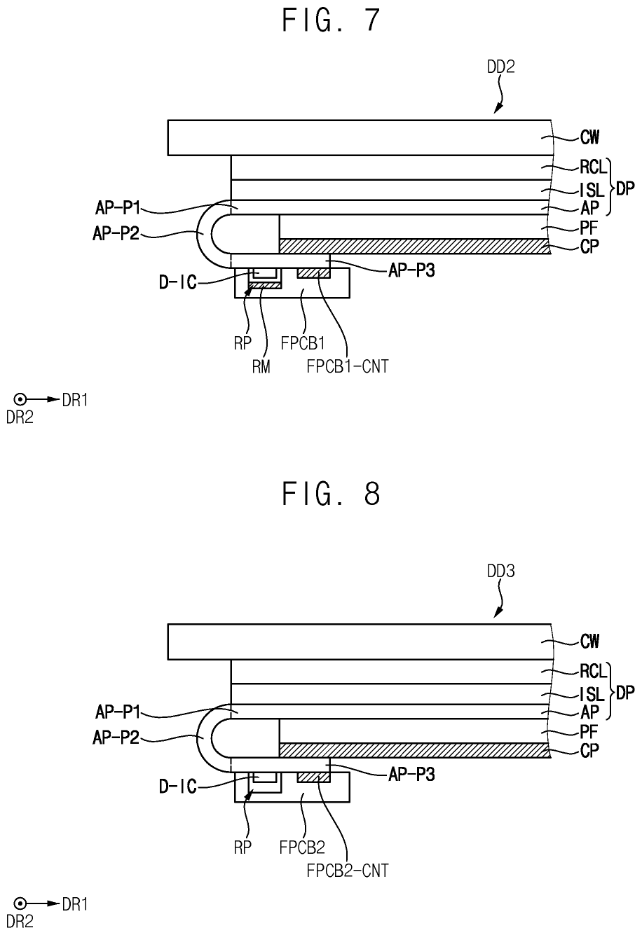

FIG. 7 is a cross-sectional view illustrating a display device DD2 according to an embodiment of the present disclosure. Hereinafter, descriptions overlapping descriptions of the display device DD described with reference to FIG. 4B will be omitted or simplified.

Referring to FIG. 7, unlike the display device DD illustrated in FIG. 4B, a display device DD2 according to an embodiment of the present disclosure may further include a radiating layer RM disposed in the groove RP to face a distal end surface of the driving chip D-IC. That is, the driving chip D-IC may be accommodated in the groove RP and may be spaced apart from the radiating layer RM, along a thickness direction of the first printed circuit board FPCB1. Alternatively, the driving chip D-IC may contact the radiating layer RM.

When the driving chip D-IC is accommodated in the groove RP, heat generated from the driving chip D-IC may not be dissipated smoothly due to being blocked by a printed circuit board. Accordingly, problems such as a change in characteristics of the driving chip D-IC and damage to a plurality of lines included in the printed circuit board may occur.

To prevent this, the display device DD2 according to an embodiment of the present disclosure may further include the radiating layer RM disposed in the groove RP to face the driving chip D-IC.

In an embodiment, the radiating layer RM may include graphite, copper (Cu), a metal-insulator-metal (“MIM”) sheet, etc., that is, at least one of graphite, copper (Cu), a metal-insulator-metal (“MIM”) sheet, etc.). These may be used alone or in combination with each other. Accordingly, the heat generated from the driving chip D-IC may be absorbed by the radiating layer RM as a heat radiating pattern or layer, and the heat absorbed by the radiating layer RM may be quickly dispersed within the radiating layer RM. That is, the heat generated from the driving chip D-IC may be effectively dissipated, and a phenomenon in which a change in characteristics of the driving chip D-IC and damage to the plurality of lines included in the printed circuit board may be improved.

FIG. 8 is a cross-sectional view illustrating a display device DD3 according to an embodiment of the present disclosure. FIG. 9 is a cross-sectional view illustrating a printed circuit board included in the display device DD3 of FIG. 8. Hereinafter, descriptions overlapping descriptions of the display device DD described with reference to FIG. 4B will be omitted or simplified.

Referring to FIGS. 8 and 9, unlike the display device DD illustrated in FIG. 4B, a display device DD3 according to an embodiment of the present disclosure may include a second printed circuit board FPCB2 defining a groove RP and including a base layer BL, a conductive layer DL disposed on the base layer BL, and a coverlay layer CL disposed on the conductive layer DL. In addition, the groove RP may be defined by an opening exposing a part of the conductive layer DL to outside the coverlay layer CL. In other words, the coverlay layer CL of the second printed circuit board FPCB2 may not be disposed in an area overlapping the groove RP on a plane, and may be considered disconnected in a direction along the base layer BL.

The second printed circuit board FPCB2 may include a connection part FPCB2-CNT at which the second printed circuit board FPCB2 is electrically connected to the plurality of pads PD. The connection part FPCB2-CNT of the second printed circuit board FPCB2 may be positioned inside an edge of the second printed circuit board FPCB2 as similarly described herein for other printed circuit boards.

As illustrated in FIG. 9, the coverlay layer CL may cover a part of the conductive layer DL. In this case, the coverlay layer CL may expose a part of the conductive layer DL in an area overlapping or corresponding to the groove RP on a plane. That is, the driving chip D-IC may be accommodated in the groove RP and may face an exposed part DL-OP of the conductive layer DL. In an embodiment, the driving chip D-IC and the exposed part DL-OP of the conductive layer DL may be spaced apart from each other such as to define a gap therebetween (like an empty space, air-filled space, etc.).

The conductive layer DL may include a metal, an alloy, a metal nitride, a conductive metal oxide, a transparent conductive material, etc. These may be used alone or in combination with each other. For example, the conductive layer DL may include copper (Cu). Accordingly, heat generated from the driving chip D-IC may be absorbed into the exposed part DL-OP of the conductive layer DL. That is, the heat generated from the driving chip D-IC may be effectively dissipated. The conductive layer DL may function as a heat dissipating layer or heat absorbing layer. The exposed part DL-OP of the conductive layer DL may be connected to a ground of the second printed circuit board FPCB2.

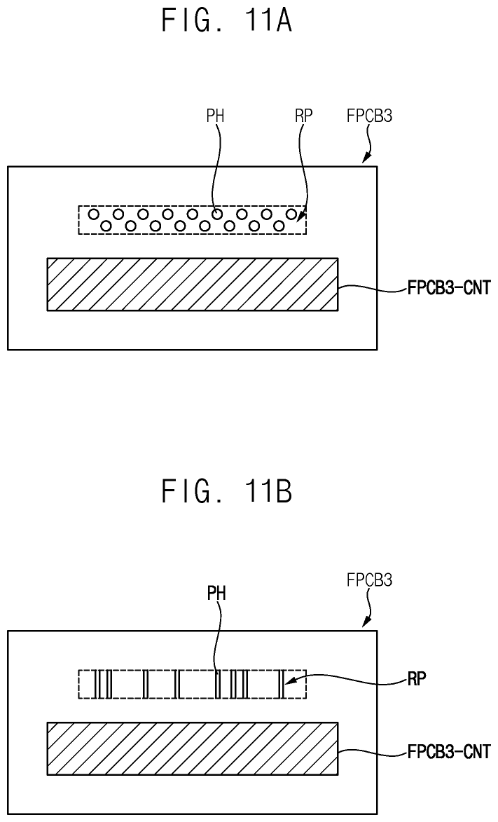

FIG. 10 is a cross-sectional view illustrating a display device DD4 according to an embodiment of the present disclosure. FIGS. 11A and 11B are plan views illustrating a printed circuit board included in the display device DD4 of FIG. 10. Hereinafter, descriptions overlapping descriptions of the display device DD described with reference to FIG. 4B will be omitted or simplified.

Referring to FIGS. 10, 11A, and 11B, unlike the display device DD of FIG. 4B, a display device DD4 according to an embodiment of the present disclosure may include a third printed circuit board FPCB3 defining a groove RP, and a penetrating hole PH provided in plural including a plurality of penetrating holes PH in an area overlapping the groove RP on a plane. The third printed circuit board FPCB3 may include a connection part FPCB3-CNT electrically connected to the plurality of pads PD. The connection part FPCB3-CNT of the third printed circuit board FPCB3 may be positioned inside an edge of the third printed circuit board FPCB3.

Referring to FIG. 10 together with FIG. 11A, the penetrating hole PH may be open at both of opposing surfaces of the circuit board, at the groove RP. The penetrating hole PH may be defined in a reduced-thickness portion of the circuit board which defines the groove RP together with a thickness portion adjacent to the groove RP. Heat generated from the driving chip D-IC may be dissipated to the outside of the display device DD4 through the plurality of penetrating holes PH as a heat dissipator or heat dissipating member. That is, the heat generated from the driving chip D-IC may be effectively dissipated, and a phenomenon in which a change in characteristics of the driving chip D-IC and damage to the plurality of lines included in the printed circuit board may be improved.

The penetrating hole PH may have a discrete planar shape defined by a solid portion of a body of the printed circuit board, where a respective connecting part is disposed or embedded in the body. As illustrated in FIG. 11A, the plurality of penetrating holes PH may have a circular shape as a discrete planar shape, but the present disclosure is not limited thereto. For example, as illustrated in FIG. 11B, the plurality of penetrating holes PH may have a rectangular shape as a discrete planar shape. Referring to FIGS. 11A and 11B, the penetrating holes PH may be spaced apart from each other along the first direction DR1 and/or the second direction DR2.

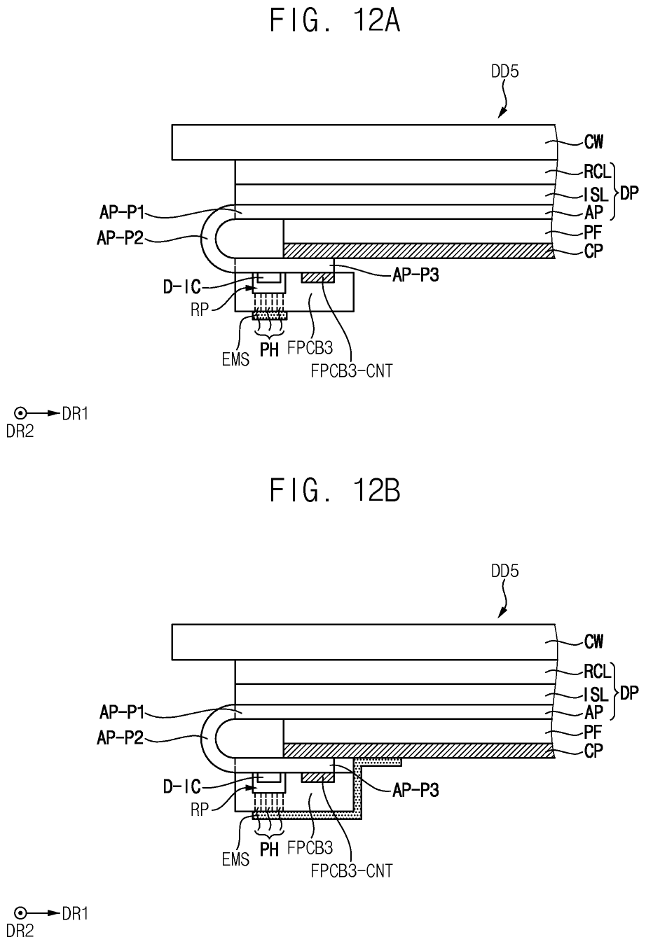

FIGS. 12A and 12B are cross-sectional views illustrating a display device DD5 according to an embodiment of the present disclosure. Hereinafter, descriptions overlapping descriptions of the display device DD4 described with reference to FIG. 10 will be omitted or simplified.

Referring to FIG. 12A, unlike the display device DD4 illustrated in FIG. 10, a display device DD5 according to an embodiment of the present disclosure may further include an electromagnetic shielding layer EMS disposed on the third printed circuit board FPCB3 in an area overlapping the groove RP on a plane.

The electromagnetic shielding layer EMS may include a metal, an alloy, a metal nitride, a conductive metal oxide, a transparent conductive material, etc. In an embodiment, the electromagnetic shielding layer EMS may include a transparent conductive material. Examples of material that may be used as the electromagnetic shielding layer EMS may include indium tin oxide (ITO), indium zinc oxide (IZO), etc. These may be used alone or in combination with each other.

An external device (not shown) may be disposed under the display substrate AP. For example, the external device may face the display substrate AP which is bent, with the driving chip D-IC and the printed circuit board therebetween. The electromagnetic shielding layer EMS may protect the driving chip D-IC from electrical overstress (“EOS”) generated by the external device. The electromagnetic shielding layer EMS may be connected to a ground of the third printed circuit board FPCB3.

Referring to FIG. 12A, the electromagnetic shielding layer EMS may be an electromagnetic shielding pattern. The electromagnetic shielding layer may be spaced apart from outer edges of the third printed circuit board FPCB3 in the first direction DR1 and/or the second direction DR2.

Referring to FIG. 12B, in an embodiment, the electromagnetic shielding layer EMS may extend along the third printed circuit board FPCB3, such as along a rear surface and a side surface, in a direction toward the cover panel CP. The electromagnetic shielding layer EMS may extend further than the third printed circuit board FPCB3 and to the cover panel CP. That is, the electromagnetic shielding layer EMS may be commonly disposed on the third printed circuit board FPCB3 and on the cover panel CP. As the electromagnetic shielding layer EMS is disposed to extend from the third printed circuit board FPCB3 to the cover panel CP, the electromagnetic shielding layer EMS may fix the third printed circuit board FPCB3 relative to a stacked structure of the display device DD5. In detail, the electromagnetic shielding layer EMS disposed to extend from the third printed circuit board FPCB3 to the cover panel CP may fix the third printed circuit board FPCB3 to the cover panel CP and to the display substrate AP.

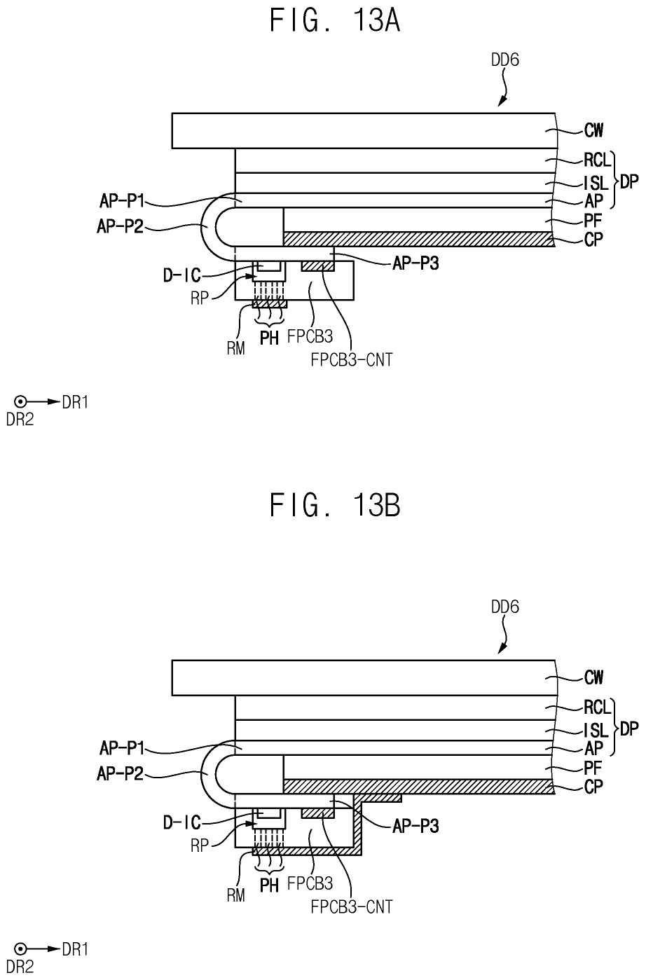

FIGS. 13A and 13B are cross-sectional views illustrating a display device DD6 according to an embodiment of the present disclosure. Hereinafter, descriptions overlapping descriptions of the display device DD4 described with reference to FIG. 10 will be omitted or simplified.

Referring to FIGS. 13A and 13B, unlike the display device DD4 illustrated in FIG. 10, as illustrated in FIG. 13A, a display device DD6 according to an embodiment of the present disclosure may further include the radiating layer RM disposed on the third printed circuit board FPCB3 in an area overlapping the groove RP on a plane.

Referring to FIG. 13A, the radiating layer RM is outside of the from the third printed circuit board FPCB3, as compared to inside the from the printed circuit board as shown in FIG. 7. The outside radiating member of FIG. 13A may be a heat radiating pattern spaced apart from outer edges of the third printed circuit board FPCB3, like the electromagnetic shielding pattern in FIG. 12A. In addition, as illustrated in FIG. 13B, the radiating layer RM may extend from the third printed circuit board FPCB3 to the cover panel CP, similar to the electromagnetic shielding pattern of FIG. 12B.

In an embodiment, the radiating layer RM may include graphite, copper, a metal-insulator-metal (“MIM”) sheet, etc. These may be used alone or in combination with each other. Heat generated from the driving chip D-IC may be transferred to the radiating layer RM disposed on the third printed circuit board FPCB3 through the plurality of penetrating holes PH. The heat emitted from the penetrating holes PH is absorbed by the radiating layer RM, and the heat absorbed by the radiating layer RM may be quickly dispersed within the radiating layer RM such as in a direction along the outer surface of the third printed circuit board FPCB3 and even to the cover panel CP. That is, the heat generated from the driving chip D-IC may be effectively dissipated.

In an embodiment, the radiating layer RM may include a thermal interface material (“TIM”). For example, the thermal interface material may include a silicone-based elastomer, silicone-based grease, etc. These may be used alone or in combination with each other. In this case, the radiating layer RM may be disposed between the third printed circuit board FPCB3 and an external device (not shown) that may be disposed under the display substrate AP. Here, the display substrate AP, the third printed circuit board FPCB3, the radiating layer RM and the external device may be in order along the thickness direction (e.g., the downward direction in FIGS. 13A and 13B, for example). In addition, the radiating layer RM may be disposed between the external device and the cover panel CP. Here, the cover panel CP, the radiating layer RM and the external device may be in order along the thickness direction (e.g., in a direction away from the display surface or front surface of the display device DD6, like the downward direction in FIGS. 13A and 13B, for example). The radiating layer RM may transfer heat generated from the driving chip D-IC to the external device so that the heat generated from the driving chip D-IC may be effectively dissipated.

In an embodiment, referring to the shapes and positions of the electromagnetic shielding layer EMS and the radiating layer RM in FIGS. 12A to 13B, a layer combining the electromagnetic shielding function and the heat radiation function may correspond to such shapes and positions.

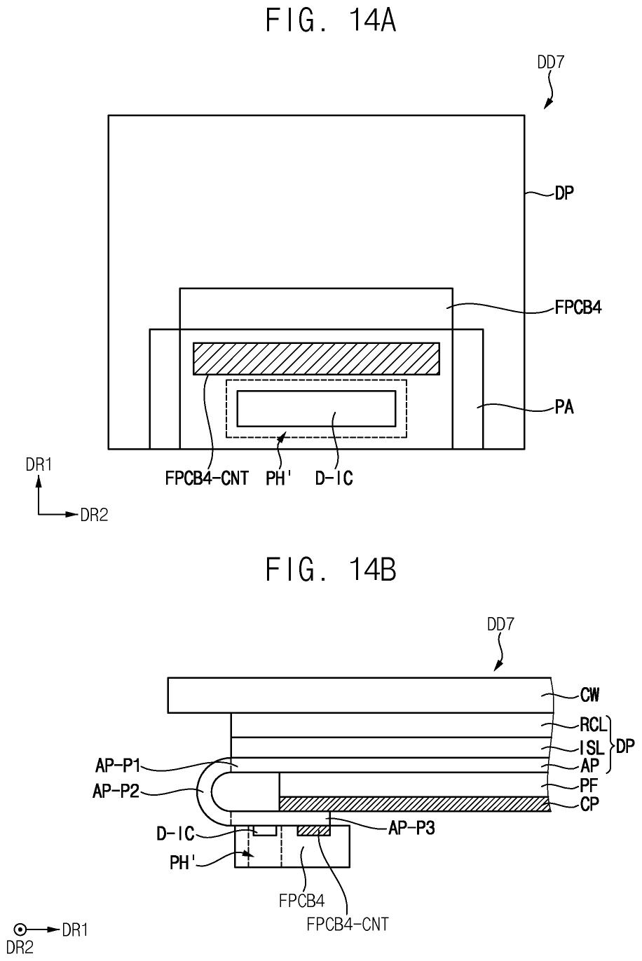

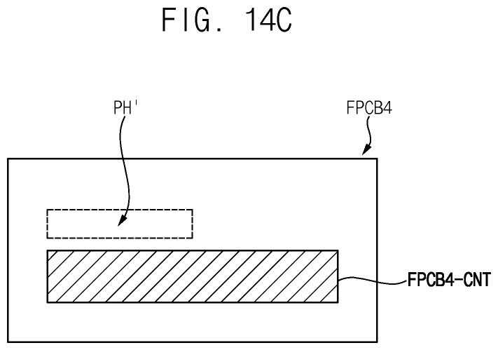

FIG. 14A is a plan view illustrating a display device DD7 according to an embodiment of the present disclosure. For example, FIG. 14A is a plan view illustrating a bent state of a display device DD7. FIG. 14A may be a rear view of the display device DD7 which is bent. FIG. 14B is a cross-sectional view illustrating the display device DD7 of FIG. 14A. FIG. 14C is a plan view illustrating a printed circuit board included in the display device DD7 of FIG. 14A. Hereinafter, descriptions overlapping descriptions of the display device DD described with reference to FIGS. 4A and 4B will be omitted or simplified.

Referring to FIGS. 14A, 14B, and 14C, unlike the display device DD illustrated in FIGS. 4A and 4B, the display device DD7 according to an embodiment of the present disclosure may include a fourth printed circuit board FPCB4 defining a penetrating opening PH′ in an area overlapping the driving chip D-IC. The fourth printed circuit board FPCB4 may include a connection part FPCB4-CNT at which the fourth printed circuit board FPCB4 is electrically connected to the plurality of pads PD. The connection part FPCB4-CNT of the fourth printed circuit board FPCB4 may be positioned inside an edge of the fourth printed circuit board FPCB4.

The penetrating opening PH′ may be a through hole extended through an entire thickness of the fourth printed circuit board FPCB4, at a planar area corresponding to the driving chip D-IC. Similar to the penetrating hole PH described above, the penetrating opening PH′ may be open at both of opposing surfaces of the circuit board, at the groove RP. That is, as illustrated in FIG. 14A, the driving chip D-IC may not be covered by the fourth printed circuit board FPCB4. A material portion (e.g., a solid portion) of the fourth printed circuit board FPCB4 may be omitted at the penetrating opening PH′. In other words, the driving chip D-IC may be exposed to the outside of the display device DD7 by the penetrating opening PH′ defined by a solid portion of the fourth printed circuit board FPCB4. Accordingly, heat generated from the driving chip D-IC may be dissipated directly to the outside of the display device DD7 through the penetrating opening PH′. That is, the heat generated from the driving chip D-IC may be effectively dissipated, and a phenomenon in which a change in characteristics of the driving chip D-IC and damage to the plurality of lines included in the printed circuit board may be improved.

The penetrating opening PH′ may be defined inside the edge of the fourth printed circuit board FPCB4. However, the present disclosure is not limited thereto. For example, as illustrated in FIG. 14C, the penetrating opening PH' may be defined adjacent to the edge of the fourth printed circuit board FPCB4.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a display substrate including a display area, a pixel in the display area, a pad area adjacent to the display area, and a pad in the pad area;
a driving chip on the display substrate, in the pad area; and
a circuit board which is on the display substrate and electrically connected to the display substrate at the pad, the circuit board defining a groove of the circuit board and covering the driving chip at the groove.

2. The display device of claim 1, wherein the circuit board includes:
a connection part which electrically connects the circuit board to the pad of the display substrate, and
the connection part inside an edge of the circuit board.

3. The display device of claim 1, wherein
an inner wall of the circuit board defines the groove of the circuit board, and
the driving chip is in the groove of the circuit board and is spaced apart from the inner wall of the circuit board.

4. The display device of claim 1, wherein the circuit board includes a heat radiating layer which is in the groove and facing the driving chip.

5. The display device of claim 4, wherein the heat radiating layer which is in the groove of the circuit board includes at least one of graphite, copper and a metal-insulator-metal sheet.

6. The display device of claim 1, wherein the circuit board includes:
a base layer;
a conductive layer on the base layer; and
a coverlay layer covering the conductive layer.

7. The display device of claim 6, wherein within the circuit board,
the coverlay layer defines an opening exposing the conductive layer to outside the circuit board, and
the groove is defined by the opening in the coverlay layer together with the conductive layer.

8. The display device of claim 1, wherein
the display substrate further includes:
a first area including the pixel;
a second area which extends from the first area, the display substrate being bendable at the second area to have a curvature; and
a third area extending from the second area and including the pad,
the display substrate which is bent at the second area includes the third area facing the first area.

9. A display device comprising:
a display substrate including a display area, a pixel in the display area, a pad area adjacent to the display area, and a pad in the pad area;
a driving chip on the display substrate, in the pad area; and
a circuit board which is on the display substrate and electrically connected to the display substrate at the pad,
wherein
the circuit board defines a groove of the circuit board corresponding to the driving chip and a plurality of penetrating holes of the circuit board which correspond to the groove, and
the circuit board covers the driving chip, at the groove of the circuit board.

10. The display device of claim 9, wherein the circuit board includes:
a connection part which electrically connects the circuit board to the pad of the display substrate, and
the connection part inside an edge of the circuit board.

11. The display device of claim 9, wherein
an inner wall of the circuit board defines the groove of the circuit board, and
the driving chip is in the groove of the circuit board and is spaced apart from the inner wall of the circuit board.

12. The display device of claim 9, further comprising:
an electromagnetic shielding layer on the circuit board, in an area of the circuit board which corresponds to the groove.

13. The display device of claim 12, further comprising:
a cover panel facing the display area of the display substrate,
wherein the electromagnetic shielding layer which is on the circuit board extends from the circuit board to the cover panel.

14. The display device of claim 9, further comprising:
a heat radiating layer on the circuit board, in an area of the circuit board which corresponds to the groove.

15. The display device of claim 14, further comprising:
a cover panel facing the display area of the display substrate,
wherein the heat radiating layer which is on the circuit board extends from the circuit board to the cover panel.

16. The display device of claim 15, wherein the heat radiating layer includes at least one of graphite, copper and a metal-insulator-metal sheet.

17. The display device of claim 15, wherein the heat radiating layer includes a thermal interface material.

18. The display device of claim 9, wherein the display substrate further includes:
a first area including the pixel;
a second area which extends from the first area, the display substrate being bendable at the second area to have a curvature; and
a third area extending from the second area and including the pad,
wherein the display substrate which is bent at the second area includes the third area facing the first area.

19. A display device comprising:
a display substrate including a display area, a pixel in the display area, a pad area adjacent to the display area, and a pad in the pad area;
a driving chip on the display substrate, in the pad area; and
a circuit board which is on the display substrate and electrically connected to the display substrate at the pad,
wherein
the circuit board defines a groove of the circuit board corresponding to the driving chip and a penetrating hole of the circuit board which corresponds to the driving chip, and
the circuit board covers the driving chip, at the groove of the circuit board.

20. The display device of claim 19, wherein the circuit board includes:
a connection part which electrically connects the circuit board to the pad of the display substrate, and
the connection part inside an edge of the circuit board.
